(19) United States
(12) Patent Application Publication
(10) Pub. No.: US 2011/0150142 A1
(43) Pub. Date: Jun. 23, 2011

(54) DISCRETE TIME RECEIVER

(75) Inventor: Young Jae LEE, Buk-gu (KR)

(73) Assignee: ELECTRONICS AND TELECOMMUNICATIONS RESEARCH INSTITUTE, Daejon (KR)

(21) Appl. No.: 12/971,114

(22) Filed: Dec. 17, 2010

(30) Foreign Application Priority Data
Dec. 18, 2009 (KR) 10-2009-0127534
Nov. 18, 2010 (KR) 10/2010-0115079

(51) Int. Cl. H03K 9/00; H04L 25/10

(52) U.S. Cl. 375/318; 375/316

(57) ABSTRACT

A discrete-time receiver includes: a sampling mixer sampling an input signal according to a sampling clock; a discrete-time filter adjusting a decimation rate by using a control signal and filtering the sampled signal by using a filter clock; and a clock generator generating a sampling clock to be supplied to the sampling mixer, and generating the control signal and the filter clock by comparing the frequency of the sampling clock with a pre-set output frequency. Over a broadband input signal, a dynamic range of an output signal can be improved.

### CROSS-REFERENCE TO RELATED APPLICATIONS

This application claims the priority of Korean Patent Application Nos. 10-2009-0127534 filed on Dec. 18, 2009 and 10-2010-0115079 filed on Nov. 18, 2010, in the Korean Intellectual Property Office, the disclosures of which are incorporated herein by reference.

### BACKGROUND OF THE INVENTION

1. Field of the Invention

The present invention relates to an RF discrete-time receiver covering a broad band (or a wide band).

2. Description of the Related Art

Conventionally, an analog-type continuous-time receiver has been widely used, and recently, a discrete-time receiver has been developed to be applied to a plurality of products. However, the recent discrete-time receiver has a narrow operation band, so its application is therefore limited.

Referring to the structure of the discrete-time receiver, an element such as an SDR (Software Defined Radio) supports a broad band operation (or a wide band operation), causing no problem in processing a broadband signal, but an ADC, a core element of the discrete-time receiver, cannot sufficiently support the broad band in the operation speed, conversion performance, and the like thereof.

A filter used for the discrete-time receiver may be classified as one of an RF area filter and a baseband area filter. The RF area filter is directly connected to a sampling mixer so as to operate in a high sampling frequency, and the baseband area filter is connected to an analog mixer so as to filter a signal having a lower frequency. The baseband filter operates at a low frequency, and because its sampling frequency is fixed, the baseband filter exhibits excellent performance. In comparison, the RF area filter requires a special design because it must have a certain performance in a broad band as well as operate in a high frequency.

FIG. 1 is a schematic block diagram of a related art discrete-time receiver.

With reference to FIG. 1, the related art discrete-time receiver 10 includes an LNTA 16, a sampling mixer 11, a first IIR filter 12, an FIR filter 13, a second IIR filter 14, and a variable amplifier 15.

The LNTA 16 is an element formed by combining functions of an LNA and a TA (Trans-conductance Amplifier), which amplifies a signal received through an antenna and converts a voltage signal into a current signal.

The sampling mixer 11, while converting a received high frequency signal into a signal of a sampling frequency band, converts an analog signal into a digital signal.

The first IIR filter, the FIR filter 13, and the second IIR filter 14 receive the sampled signal and perform decimation filtering thereon. In particular, the FIR filter 13 eliminates aliasing as well as performs filtering with various types of decimation rates according to input filtering control signals. Also, the first and second IIR filters 12 and 14 cancel an interference signal, or the like, existing in the vicinity of a desired signal band. In addition, in order to regulate a cut-off frequency, the second IIR filter 14 connects a capacitor bank to a switch to change the capacitance of the capacitor according to the operation of the switch, thus regulating the cut-off frequency.

The signal, which has passed through the second IIR filter 14, is amplified by the variable amplifier 15 and then input to the ADC. In particular, if the swing width of the signal which has passed through the second IIR filter 14 is small, the range of the signal that can be detected by the ADC is reduced to degrade the overall SNR performance of a receiver, so the swing width is secured by using the variable amplifier 15.

FIG. 2 is a schematic block diagram of a related art RF receiver.

The RF receiver 20 illustrated in FIG. 2 has different operational characteristics from those of the receiver 10 illustrated in FIG. 1. The RF receiver 20 illustrated in FIG. 2 may process a broadband input signal. An input signal is amplified by an LNA, and a mixer 21, which is similar to an existing analog receiver, lowers the frequency of the input signal by using an I/O clock input from a frequency synthesizer 22. Analog filters 23, 24, and 25 create a frequency mask of the receiver.

A sampling mixer 28 operates with a fixed sampling frequency fs. Thus, the sampling frequency fs of the signal must be lowered to be a signal having an operation frequency of the ADC in blocks following the sampling mixer 28. To this end, decimation filters 26 and 27 filter input signals according to a set decimation rate. In the receiver 20, illustrated in FIG. 2, the decimation rates are ¼ and ⅓, respectively. Clocks used for the operations of the decimation filters 26 and 27 are provided by a clock generator 29.

In terms of the overall performance and circuit design, the RF receiver 20 illustrated in FIG. 2, except for the decimation filters 26 and 27, has superior performance to the discrete-time receiver 10 of FIG. 1, but is disadvantageous in that its structure is almost similar to the existing analog structure and main blocks are used.

Namely, in order to improve the performance of the discrete-time filter, the number of stages of the discrete-time filter needs to be reduced. Thus, it is desirous to reduce the number of filters and increase the sampling frequency of the ADC.

Referring to the order of the used filters, the discrete-time filter 10 illustrated in FIG. 1 uses the primary sinc filter 13 while the discrete-time filter 20 illustrated in FIG. 2 uses the secondary sinc filters 26 and 27 to widen the width of the null and deepen the depth of the null to eliminate aliasing.

The recent discrete-time filters are applied to an application field in which a bandwidth is narrow in a narrow band. However, as the application field having a wide bandwidth such as broad band such as an LTE (Long-Term Evolution) or DVB-H (Digital Video Broadcasting-Handheld) has emerged, the discrete-time receiver structure is required to be designed to process a broadband signal.

### SUMMARY OF THE INVENTION

An aspect of the present invention provides a discrete-time receiver capable of performing sampling in an RF area and enabling an analog-to-digital converter (ADC) to have high resolution by adjusting a decimation rate according to a sampling frequency to lower the frequency of an output signal so as to become a sampling frequency of the ADC.

According to an aspect of the present invention, there is provided a discrete-time receiver including: a sampling mixer sampling an input signal according to a sampling clock; a discrete-time filter adjusting a decimation rate by using a control signal and filtering the sampled signal by using a filter clock; and a clock generator generating a sampling clock to be supplied to the sampling mixer, and generating the control signal and the filter clock by comparing the frequency of the sampling clock with a pre-set output frequency.

According to another aspect of the present invention, there is provided a discrete-time receiver including: an amplifying unit including a low-noise amplifier amplifying an input voltage signal and a voltage amplifier increasing a dynamic range of an output signal from the low-noise amplifier; a voltage current conversion unit converting an output signal from the amplifying unit into a current signal; a sampling mixer sampling the current signal according to the sampling clock; a discrete-time filter adjusting a decimation rate by using a control signal and filtering the sampled signal by using a filter clock; and a clock generator generating a sampling clock to be supplied to the sampling mixer, and generating the control signal and the filter clock by comparing the frequency of the sampling clock with a pre-set output frequency.

According to another aspect of the present invention, there is provided a discrete-time receiver including: a voltage current conversion unit converting an input voltage signal into a current signal; a sampling mixer sampling the current signal according to a sampling clock; a discrete-time filter adjusting a decimation rate by using a control signal and filtering the sampled signal by using a filter clock; a clock generator generating a sampling clock to be supplied to the sampling mixer, and generating the control signal and the filter clock by comparing the frequency of the sampling clock with a pre-set output frequency; and an amplifying unit including a low-noise amplifier amplifying the input signal and supplying the amplified signal to the voltage current conversion unit and a current amplifier increasing a dynamic range of an output signal from the sampling mixer and supplying the same to the discrete-time filter.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic block diagram of a related art discrete-time receiver;

FIG. 2 is a schematic block diagram of a related art RF receiver;

FIG. 3 is a function block diagram of a discrete-time receiver according to an exemplary embodiment of the present invention;

FIG. 4 is a function block diagram of a discrete-time receiver according to another exemplary embodiment of the present invention;

FIG. 5 is a function block diagram of a discrete-time receiver according to another exemplary embodiment of the present invention; and

FIG. 6 is a function block diagram of a discrete-time receiver according to another exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and dimensions may be exaggerated for clarity, and the same reference numerals will be used throughout to designate the same or like components.

Unless explicitly described to the contrary, the word “comprise” and variations such as “comprises” or “comprising,” will be understood to imply the inclusion of stated elements but not the exclusion of any other elements.

A discrete-time receiver according to an exemplary embodiment of the present invention proposes a receiver structure that can be used in various application fields by using a discrete-time filter. Various types of discrete filters may be arranged in parallel according to a decimation rate and the width and depth of a null (or nul) of a filter in use, and selected according to the specification of an application field. Also, the discrete-time receiver according to an exemplary embodiment of the present invention has a structure in which the decimation rate of a decimation filter can be adjustable in order to allow a frequency of a signal after the decimation filter to agree with a sampling frequency of an ADC. Also, in order to obtain a wide dynamic range, the discrete-time receiver according to an exemplary embodiment of the present invention includes variable amplifiers at a front or rear stage of a mixer to thus secure signal levels that can be processed by the ADC.

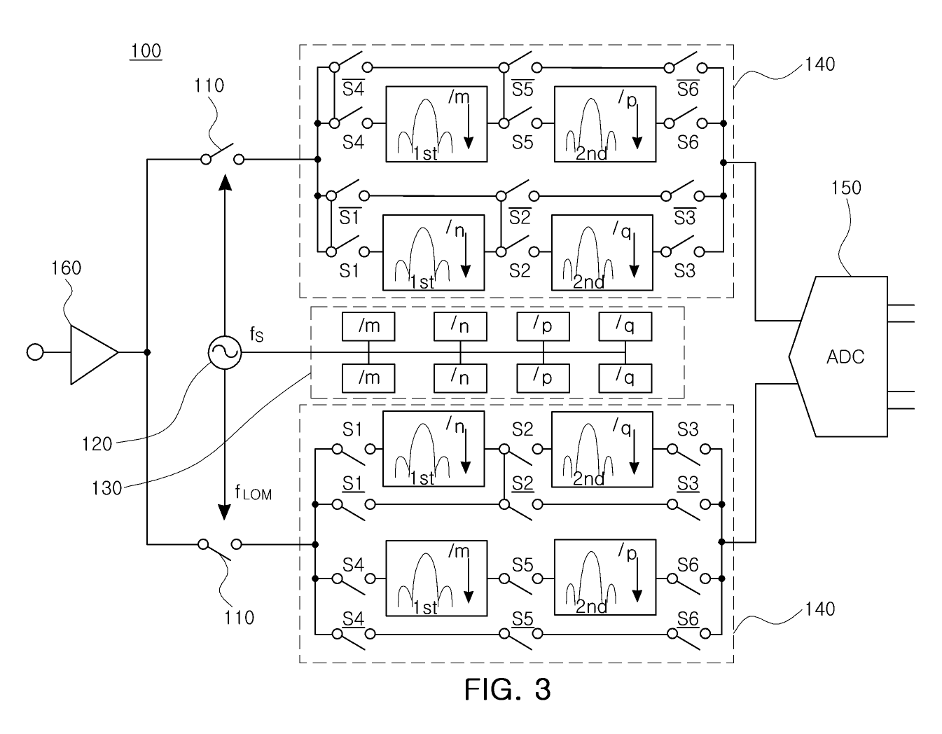

FIG. 3 is a function block diagram of a discrete-time receiver according to an exemplary embodiment of the present invention. A discrete-time receiver 100 illustrated in FIG. 3 is illustrated to be simplified in order to explain association operations of a sampling mixer 110 and a discrete-time filter 140 applicable to a broad band. The operation of the discrete-time receiver 100 will now be described with reference to FIG. 3.

A voltage signal input to the discrete-time receiver 100 is amplified and then converted into a current signal by an LNTA 160.

The sampling mixer 110 samples the input current signal according to a sampling frequency, thus lowering the frequency of the input signal to a baseband and converting it into a discrete signal. The two sampling mixers 110 operate according to a sampling clock, while having the same frequency and a 180-degree phase difference.

The discrete-time filter 140 is implemented to have a structure in which primary and secondary decimation filters having various decimation rates m, n, p and q are connected in parallel. Signal filtering can be performed and the decimation rate can be adjusted by controlling switching of switches S1, S2, S3, S4, S5, and S6 connected to inputs/outputs of the discrete-time filter 140. Namely, the discrete-time filter 140 determines the decimation rate according to the frequency of the input signal and combines the primary and secondary decimation filters to implement a desired decimation rate by controlling the switching of the switches. If only the switch S1 is selected, a filter having a decimation rate of n of the primary filter is selected, and when the switches S4, S5, and S6 are selected, the primary filter and the secondary filter are connected in series and a filter having a decimation rate (m×p) is generated.

A clock used for the sampling mixer 110 and that used for the discrete-time filter 140 are generated by the frequency synthesizer 120 and the clock generator 130. The clock generator 130 generates a sampling clock and divides it to generate clocks to be supplied to the primary and secondary decimation filters of the discrete-time filter 140. The frequency synthesizer 120 creates two clocks having a 180-degree phase difference therebetween, while having the same frequency from the clocks generated by the clock generator 130. The clock generator 130 operates cooperatively with decimation filters.

A final output is supplied to the ADC 150, so the sampling frequency of the ADC and the clock generated by the clock generator 130 must be in synchronization.

As described above, the discrete-time receiver 100 according to an exemplary embodiment of the present invention is designed such that the band of the frequency input to the ADC 150 is within a certain range, while coping with a broadband input signal, and operates in an actual communication environment.

When the strength of input signals is sufficient, a sufficient dynamic range can be secured through the configuration of the receiver illustrated in FIG. 3. However, the strength of an input signal may be extremely low in a wireless communication channel, or the like, and as a result, the signal input to the ADC 150 may not have a sufficient dynamic range. Thus, an element which may be able to secure a dynamic range is required to be added to the discrete-time receiver 100.

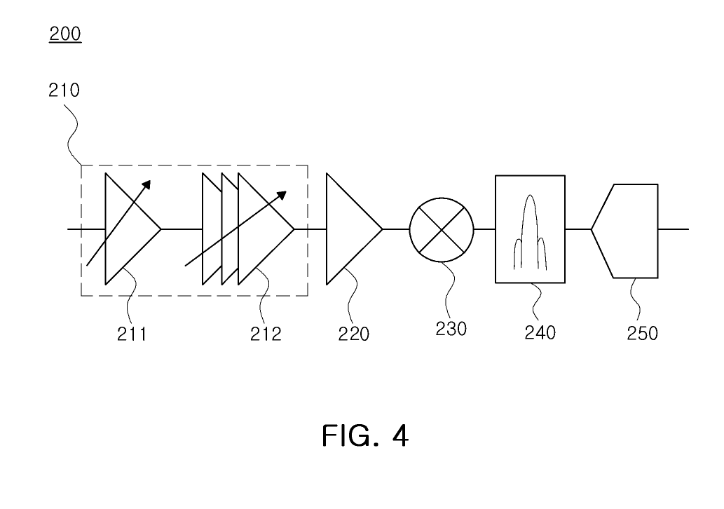

FIG. 4 is a function block diagram of a discrete-time receiver according to another exemplary embodiment of the present invention.

With reference to FIG. 4, the discrete-time receiver according to this exemplary embodiment may be configured to include an amplifier 210, a voltage current converter 220, a sampling mixer 230, and a discrete-time filter 240.

The amplifier 210 may be configured to include a low noise amplifier (LNA) 211 and a voltage amplifier 212 in order to improve a dynamic range. In this case, however, the amplifier 210 including the LNA 211 and the voltage amplifier 212 is operable, while satisfying the dynamic range, at an operation frequency of 1 GHz or lower, but the dynamic range is reduced to a frequency higher than 1 GHz.

The voltage current converter 220 may convert a voltage signal into a current signal, and converts an input signal into a signal that can be processed by the sampling mixer 230 and the discrete-time filter 240.

The operations of the sampling mixer 230 and the discrete-time filter 240 are the same as those of the sampling mixer 110 and the discrete-time filter 140 illustrated in FIG. 3, so a repeated description thereof will be omitted.

In order for the receiver 200 to obtain a wide dynamic range, the receiver 200 is preferably designed such that the LNA 211 and the voltage amplifier 212 have a wide gain variable range. Namely, the amplifier 210 is designed to sufficiently amplify a signal, whereby at the time when the amplified signal is input to the ADC, it can have a sufficient dynamic range, although there has been an operational loss at the voltage current converter 220, the sampling mixer 230, and the discrete-time filter 240.

However, in the discrete-time receiver 200 illustrated in FIG. 4, when the frequency of the input signal is increased, a gain range is reduced and power consumption is increased due to the frequency characteristics of the LNA 211 and the voltage amplifier 212, so a desired dynamic range can hardly be obtained in a high frequency.

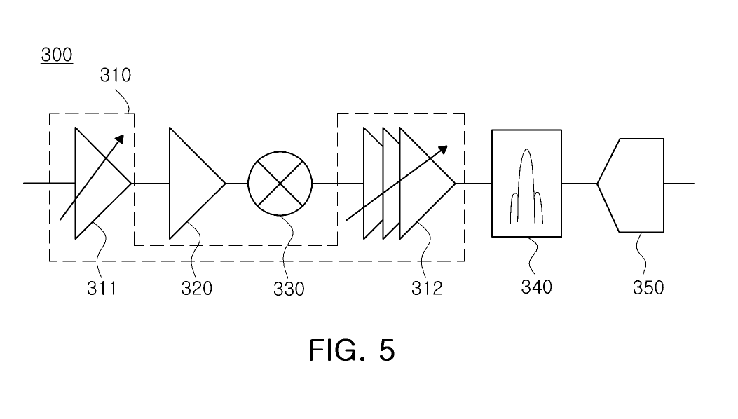

FIG. 5 is a function block diagram of a discrete-time receiver according to another exemplary embodiment of the present invention.

With reference to FIG. 5, a discrete-time receiver 300 according to the present exemplary embodiment may be configured to include an amplifier 310, a voltage current converter 320, a sampling mixer 330, and a discrete-time filter 340. The discrete-time receiver 300 illustrated in FIG. 5 can resolve the shortcomings of the discrete-time receiver 200 of FIG. 4 having a narrow dynamic range.

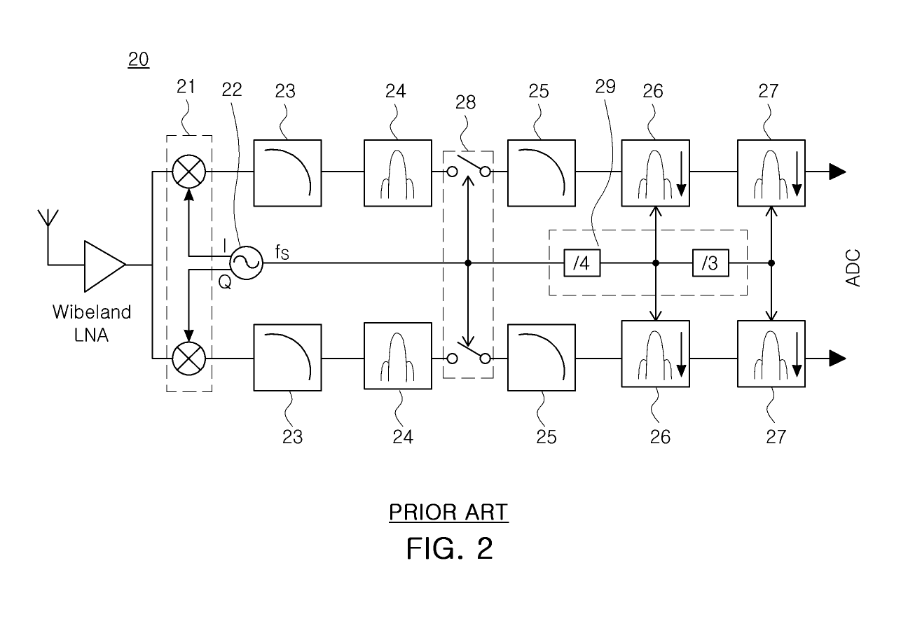

The voltage current converter 320, the sampling mixer 330, and the discrete-time filter 340 operate in the same manner as those described above with reference to FIGS. 2 and 3, so a repeated description thereof will be omitted.

The amplifier 210 illustrated in FIG. 4 is disposed only at the front stage of the voltage current converter 230 to perform amplifying, while the amplifier 310 illustrated in FIG. 5 performs amplifying even after sampling is performed by the sampling mixer, as well as performing amplifying at the front stage of the voltage current converter 220.

The amplifier 310 applied to the discrete-time receiver 300 may be configured to include an LNA 311 and a current amplifier 312. Amplifying may be performed by using only the LNA 311 having good RF characteristics in a high frequency band, and a current signal having a frequency lowered to a baseband by the sampling mixer 330 can be amplified by using the current amplifier 312. Thus, the voltage signal amplified by the LNA 311 is converted into a current signal by the current voltage converter 320, frequency-converted and then converted into a discrete signal by the sampling mixer 330. Unlike the existing structure in which a current output from the sampling mixer 330 is directly transmitted to the discrete-time filter 340, the gain can be varied by using the current amplifier 302 that can amplify current.

Namely, in order to obtain amplification characteristics such as a low frequency in a high frequency, more currents must be used. Thus, the problem of the degradation of amplification characteristics is solved by separating the amplification process. Namely, the secondary amplifying process is moved to a baseband to lower the frequency band and be performed with a small current.

Like the amplifier 210 illustrated in FIG. 4, the amplifier 310 illustrated in FIG. 5 is configured such that the dynamic range of the amplifier 310 is entirely covered by the current amplifier 312. Because the current amplifier 312 operates at a low frequency, it can be designed to have a wide variable gain range while using a small current.

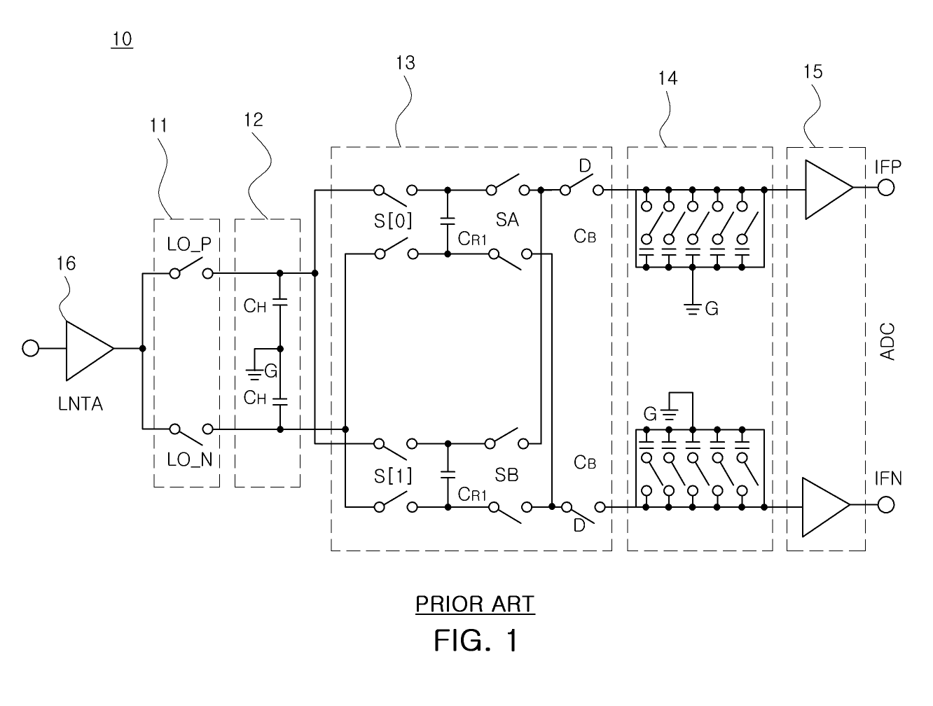

The amplified current signal is delivered to the ADC 340 through the discrete-time filter 330. In the case of the existing analog type receiver, the dynamic range is improved by using a voltage amplifier at an intermediate frequency (IF) area. Likewise, in the discrete-time receiver, as shown in FIG. 1, the dynamic range is increased by using the variable amplifier 15 after the discrete filters 12, 13, and 14. However, in the structure proposed as illustrated in FIG. 5, the dynamic range is improved by using the current amplifier 302 before the discrete-time filter 330.

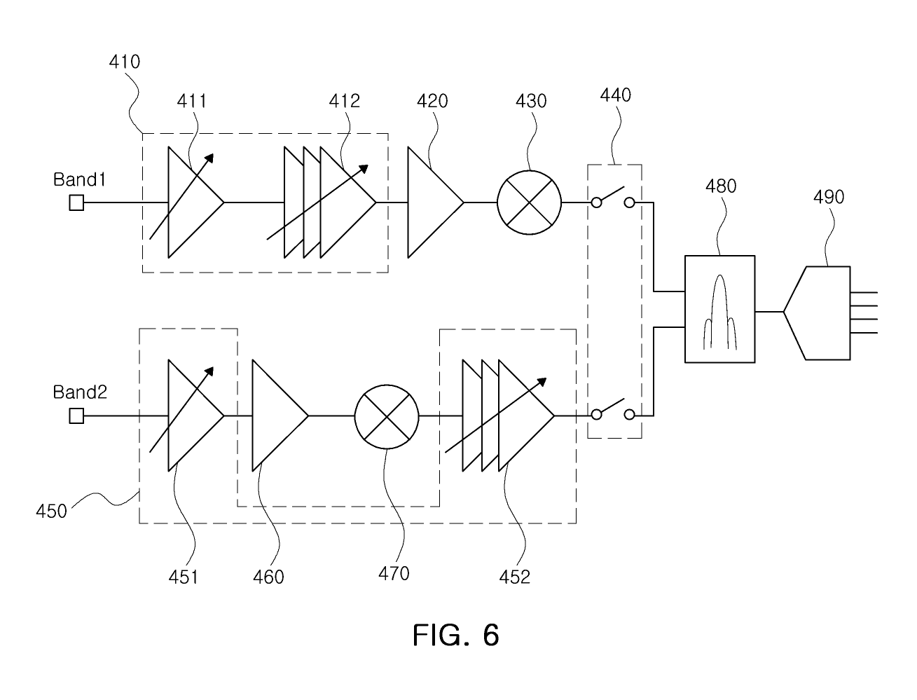

FIG. 6 is a function block diagram of a discrete-time receiver according to another exemplary embodiment of the present invention.

With reference to FIG. 6, the discrete-time receiver 400 according to the present exemplary embodiment is configured by connecting the discrete-time receiver 200 illustrated in FIG. 4 and the discrete-time receiver 300 illustrated in FIG. 5 in parallel. The discrete-time receiver 400 having such a parallel connection structure can be operable in every band, while having a sufficient dynamic range with respect to various input signals of a wide range.

Signals supplied by first and second bands to two signal paths, respectively, may be one of signals distributed by using distributor, or the like, after being received.

When the received signal has a frequency of 1 GHz or lower, the received signal is input to the first band.

The dynamic range of the input signal can be improved at the first amplifier 410 including a first LNA 411 and a voltage amplifier 412. Thereafter, the input signal, passing through a first voltage current converter 420 and a first sampling mixer 430, is turned into a sampled current signal and then delivered to a discrete-time filter 480 by a band selector 440.

When the received signal has a frequency higher than 1 GHz, the received signal is input to the second band. The input signal is amplified through a first LNA 451 and passes through a second voltage current converter 460 and a second sampling mixer 470 so as to be turned into a sampled current signal. The dynamic range of the current signal is improved by a current amplifier 452, and then the signal is delivered to a discrete-time filter 480 by a band selector 440.

In order to process a broadband signal, the part corresponding to the discrete-time filter 140 in the structure proposed in FIG. 3 can be applied to the discrete-time filter 440, to thereby regulate a sampling frequency such that it can be operated within a certain range in an ADC 490 at the rear stage.

As set forth above, the discrete-time receiver according to exemplary embodiments of the invention has an effective and wide dynamic range sufficient to cope with an input signal having a broadband frequency.

In addition, the discrete-time receiver operates with current, consumes less power, has a simple hardware configuration, and can be controlled by using a switch.

While the present invention has been shown and described in connection with the exemplary embodiments, it will be apparent to those skilled in the art that modifications and variations can be made without departing from the spirit and scope of the invention as defined by the appended claims.

What is claimed is:

1. A discrete-time receiver comprising:
a sampling mixer sampling an input signal according to a sampling clock;
a discrete-time filter adjusting a decimation rate by using a control signal and filtering the sampled signal by using a filter clock; and
a clock generator generating a sampling clock to be supplied to the sampling mixer, and generating the control signal and the filter clock by comparing the frequency of the sampling clock with a pre-set output frequency.

2. The discrete-time receiver of claim 1, wherein the discrete-time filter comprises:
a plurality of decimation filters performing filtering by using the filter clock with different decimation rates; and
a path forming unit forming a signal transmission path by selecting a portion or the entirety of the plurality of decimation filters according to the control signal.

3. The discrete-time receiver of claim 1, wherein the clock generator generates the sampling clock and the filter clock by synchronizing them.

4. The discrete-time receiver of claim 1, further comprising a low noise amplifier amplifying the input signal and supplying the amplified signal to the sampling mixer.

5. A discrete-time receiver comprising:
an amplifying unit including a low-noise amplifier amplifying an input voltage signal and a voltage amplifier increasing a dynamic range of an output signal from the low-noise amplifier;
a voltage current conversion unit converting an output signal from the amplifying unit into a current signal; a sampling mixer sampling the current signal according to the sampling clock;
a discrete-time filter adjusting a decimation rate by using a control signal and filtering the sampled signal by using a filter clock; and
a clock generator generating a sampling clock to be supplied to the sampling mixer, and generating the control signal and the filter clock by comparing the frequency of the sampling clock with a pre-set output frequency.

6. The discrete-time receiver of claim 5, wherein the amplifying unit varies an amplification rate such that a dynamic range of an output signal from the discrete-time filter is within a pre-set range.

7. The discrete-time receiver of claim 5, wherein the discrete-time filter comprises:
a plurality of decimation filters performing filtering by using the filter clock with different decimation rates; and
a path forming unit forming a signal transmission path by selecting a portion or the entirety of the plurality of decimation filters according to the control signal.

8. The discrete-time receiver of claim 5, wherein the clock generator generates the sampling clock and the filter clock by synchronizing them.

9. A discrete-time receiver comprising:
a voltage current conversion unit converting an input voltage signal into a current signal;
a sampling mixer sampling the current signal according to a sampling clock;
a discrete-time filter adjusting a decimation rate by using a control signal and filtering the sampled signal by using a filter clock;
a clock generator generating a sampling clock to be supplied to the sampling mixer, and generating the control signal and the filter clock by comparing the frequency of the sampling clock with a pre-set output frequency; and
an amplifying unit including a low-noise amplifier amplifying the input signal and supplying the amplified signal to the voltage current conversion unit and a current amplifier increasing a dynamic range of an output signal from the sampling mixer and supplying the same to the discrete-time filter.

10. The discrete-time receiver of claim 9, wherein the amplifying unit varies an amplification rate such that a dynamic range of an output signal from the discrete-time filter is within a pre-set range.

11. The discrete-time receiver of claim 9, wherein the discrete-time filter comprises:
a plurality of decimation filters performing filtering by using the filter clock with different decimation rates; and
a path forming unit forming a signal transmission path by selecting a portion or the entirety of the plurality of decimation filters according to the control signal.
